(19) United States
(12) Patent Application Publication
(10) Pub. No.: US 2024/0170398 A1
(43) Pub. Date: May 23, 2024

(54) SEMICONDUCTOR DEVICE

(71) Applicant: Renesas Electronics Corporation, Tokyo (JP)

(72) Inventors: Hiromichi TAKAOKA, Tokyo (JP); Yoshiyuki SATO, Tokyo (JP); Yuki FUJIMOTO, Tokyo (JP)

(21) Appl. No.: 18/511,535

(22) Filed: Nov. 16, 2023

(30) Foreign Application Priority Data
Nov. 17, 2022 (JP) 2022-183959

(51) Int. Cl. H01L 23/525

(52) U.S. Cl. CPC H01L 23/5256

(57) ABSTRACT

The dielectric film IF is disposed on the semiconductor substrate SB, and the plurality of electric fuse portions FU are disposed on the dielectric film IF. The n-type first well region WL1 is disposed in the semiconductor substrate SB and on the surface of the semiconductor substrate SB. The first well region WL1 is formed by integrally connecting the well region WLa located under each of the plurality of electric fuse portions FU to each other.

### CROSS-REFERENCE TO RELATED APPLICATIONS

The disclosure of Japanese Patent Application No. 2022-183959 filed on Nov. 17, 2022, including the specification, drawings and abstract is incorporated herein by reference in its entirety.

### BACKGROUND

The present disclosure relates to a semiconductor device, and can be suitably used, for example, for a semiconductor device having an electric fuse portion.

There is a disclosed technique listed below.
[Patent Document 1] Japanese Unexamined Patent Application Publication No. 2011-222691

Electric fuses that are fused by an electric current are known. Patent Document 1 discloses a technique for reliably cutting the electric fuse.

### SUMMARY

In a configuration including a plurality of electric fuse cells as in Patent Document 1, reducing a planar occupation area of a region in which a plurality of electric fuse cells are disposed is desired.

Other objects and novel features will become apparent from the description of this specification and the accompanying drawings.

According to a semiconductor device of one embodiment, a dielectric film is disposed on a semiconductor substrate, and a plurality of electric fuse portions are disposed on the dielectric film. A first well region of a first conductivity type is disposed in the semiconductor substrate and on a surface of the semiconductor substrate. The first well region is configured by integrally connecting a well region located under each of the plurality of electric fuse portions to each other.

The semiconductor device of one embodiment can reduce the planar occupation area of the region where the plurality of electric fuse portions are formed.

### BRIEF DESCRIPTION OF THE DRAWINGS

FIG. 1 is a plan view showing a configuration of a semiconductor device in a chip state according to a first embodiment.

FIG. 2 is a diagram showing a circuit of a fuse and a cut transistor.

FIG. 3 is a plan view showing the configuration of the semiconductor device according to the first embodiment.

FIG. 4 is a schematic cross-sectional view along IV-IV line of FIG. 3.

FIG. 5 is a schematic cross-sectional view along V-V line of FIG. 3.

FIG. 6 is a schematic cross-sectional view along VI-VI line of FIG. 3.

FIG. 7 is a schematic cross-sectional view along VII-VII line of FIG. 3.

FIG. 8 is a plan view showing a configuration of a semiconductor device according to a comparative example.

FIG. 9 is a cross-sectional view showing a state in which a constituent material of the electric fuse cell penetrates through the dielectric film when the electric fuse portion is fused.

FIG. 10 is a plan view showing a configuration of a semiconductor device according to a second embodiment.

FIG. 11 is a schematic cross-sectional view along XI-XI line of FIG. 10.

FIG. 12 is a plan view showing a configuration of a semiconductor device according to a third embodiment.

FIG. 13 is a schematic cross-sectional view along XIII-XIII line of FIG. 12.

### DETAILED DESCRIPTION

Hereinafter, embodiments of the present disclosure will be described in detail with reference to the drawings. In the specification and drawings, the same or corresponding components are denoted by the same reference numerals, and a repetitive description thereof is not repeated. In the drawings, for convenience of description, the configuration may be omitted or simplified. Further, at least a part of each embodiment and each modified example may be arbitrarily combined with each other.

Semiconductor devices of the embodiments described below are not limited to semiconductor chips, may be semiconductor wafers prior to being divided into semiconductor chips, also may be semiconductor packages in which the semiconductor chips are sealed with a resin. Also, in this specification, a plan view means a viewpoint viewed from a direction orthogonal to the surface of the semiconductor substrate.

### First Embodiment

### Configuration of Semiconductor Device in Chip-State

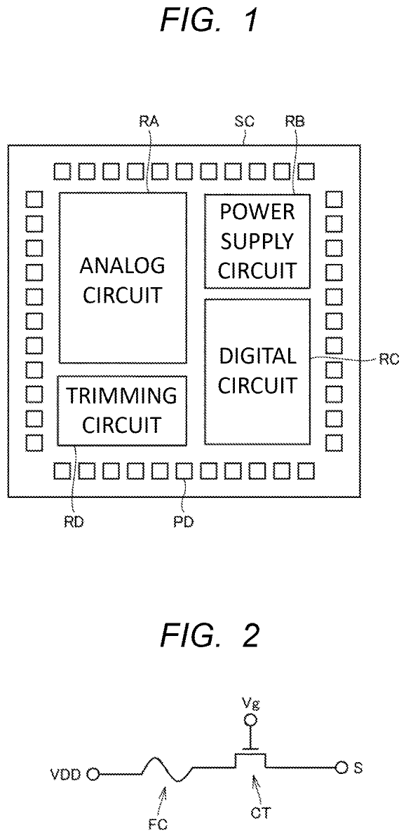

First, a configuration of a semiconductor device in a chip-state according to the first embodiment will be described with reference to FIG. 1.

As shown in FIG. 1, a semiconductor device SC in the present embodiment is, for example, a microcontroller. The semiconductor device SC is, for example, in a chip-state and has a semiconductor substrate. Electric elements are disposed on and over the surface of the semiconductor substrate. The semiconductor device SC includes, for example, an analog circuit region RA, a power supply circuit region RB, a digital circuit region RC, and a trimming circuit region RD. The semiconductor device SC has a plurality of pad electrodes PD. Each of the plurality of pad electrodes PD is electrically connected to the electric element disposed in the semiconductor device SC.

A plurality of electric fuse cells are disposed in the trimming circuit region RD. Each of the plurality of electric fuse cells has an electric fuse portion. The electric fuse portion serves to adjust the characteristic variation of the functional element having a predetermined function and to obtain a desired characteristic of the functional element by the electric fuse portion being fused and removed.

As shown in FIG. 2, the electric fuse portion in the present embodiment is not cut by irradiation with a laser beam, but is cut by flowing a current. The electric fuse portion in the present embodiment is, for example, a type that is completely disconnected in fusing and removing, and is for high accuracy and high reliability.

An electric fuse cell FC includes the electric fuse portion. The potential VDD is connected to one end of the electric fuse cell FC, and the potential S is connected to the other end of the electric fuse cell FC via a cut transistor CT. The cut transistor CT is set to ON state by inputting a signal Vg to the gate of the cut transistor CT. As a result, a current flowing through the electric fuse portion of the electric fuse cell FC generates Joule heat, and the Joule heat fuses and removes the electric fuse.

### Configuration of Electric Fuse Cell FC

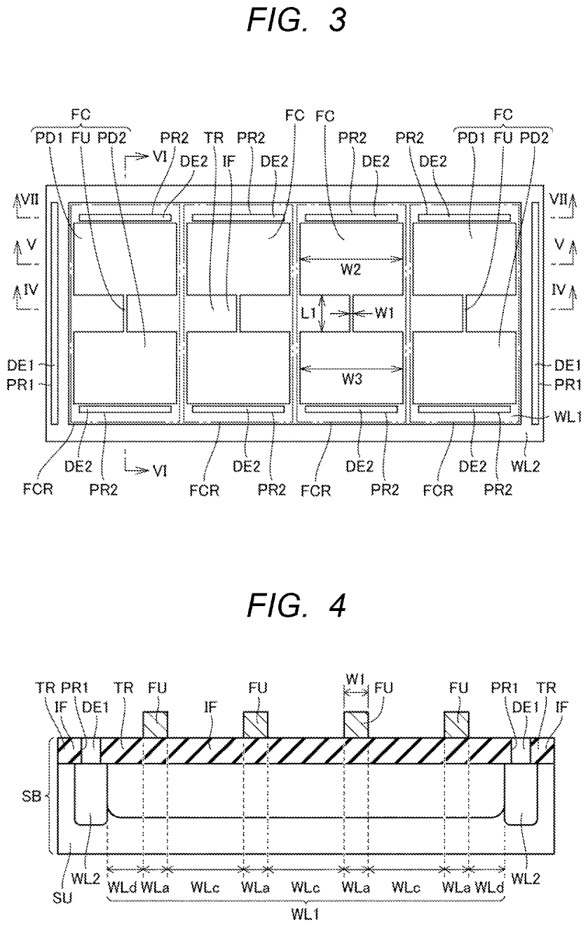

Next, a configuration of the electric fuse cell included in the semiconductor device according to the present embodiment will be described with reference to FIG. 3 to FIG. 7.

As shown in FIG. 3, the plurality of electric fuse cells FC are disposed. Each of the plurality of electric fuse cells FC includes an electric fuse portion FU, a first pad portion PD1, and a second pad portion PD2.

In plan view, the first pad portion PD1 is connected to one end portion of the electric fuse portion FU in a longitudinal direction, and the second pad portion PD2 is connected to the other end portion of the electric fuse portion FU. The dimension W1 of the electric fuse portion FU in the lateral direction is smaller than the dimension Li of the electric fuse portion FU in the longitudinal direction. The dimension W1 of the electric fuse portion FU in the lateral direction is smaller than the width W2 of the first pad portion PD1 and the width W3 of the second pad portion PD2 along the lateral direction. The width W2 of the first pad portion PD1 and the width W3 of the second pad portion PD2 are substantially the same as each other. However, the width W2 and the width W3 are not limited to be substantially the same as each other, and may be different from each other.

The plurality of electric fuse cells FC are disposed so as to be arranged along the lateral direction of the electric fuse portion FU in plan view. Further, the plurality of electric fuse portions FU are also disposed so as to be arranged along the lateral direction of the electric fuse portion FU in plan view.

As shown in FIG. 4, a semiconductor substrate SB has a surface. An element isolation structure is disposed on the surface of the semiconductor substrate SB. The element isolation structure is, for example, an STI (Shallow Trench Isolation). The STI includes a trench TR formed on the surface of the semiconductor substrate SB and a dielectric film IF filling the trench TR.

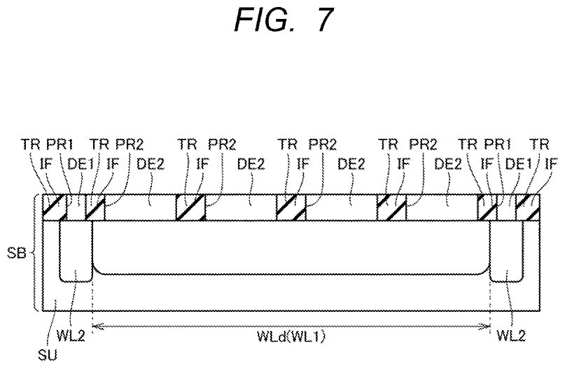

In the semiconductor substrate SB, a substrate region SU, a first well region WL1, a second well region WL2, a diffusion region DE1, and a diffusion region DE2 (FIGS. 6 and 7) are formed. The substrate region SU is disposed in the semiconductor substrate SB, and is, for example, a p-type (second conductivity type) impurity region. That is, the n-type first well region WL1, the second well region WL2, the diffusion regions DE1, DE2, and the like are formed in the semiconductor substrate SB formed entirely of the p-type substrate region SU.

The first well region WL1 is, for example, an n-type (first conductivity type) impurity region. The first well region WL1 is disposed in the semiconductor substrate SB and on the surface of the semiconductor substrate SB (the bottom surface of the trench TR). The first well region WL1 is disposed between the substrate region SU and the bottom surface of the trench TR. The first well region WL1 forms a pn junction with the substrate region SU. The first well region WL1 is configured to have a floating potential. The bottom surface of the first well region WL1 is covered with the substrate region SU.

The second well region WL2 is, for example, a p-type impurity region. The second well region WL2 is disposed over the substrate region SU. The second well region WL2 has a p-type impurity concentration higher than the p-type impurity concentration of the substrate region SU. The second well region WL2 is in contact with a side portion of the first well region WL1. The second well region WL2 and the first well region WL1 form a pn junction. The second well region WL2 is formed so as to surround the first well region WL1 in plan view.

On the surface of the semiconductor substrate SB, a convex portion (first convex portion) PR1 and a convex portion (second convex portion) PR2 (FIGS. 6 and 7) are disposed. Each of the convex portions PR1, PR2 is a region where no trench TR is formed on the surface of the semiconductor substrate SB. Each of the convex portions PR1, PR2 protrudes upward from a bottom surface (bottom portion) of the trench TR. Each of the convex portion PR1 and the convex portion PR2 is located next to the trench TR. Each of the convex portion PR1 and the convex portion PR2 is located on a side surface of the trench TR.

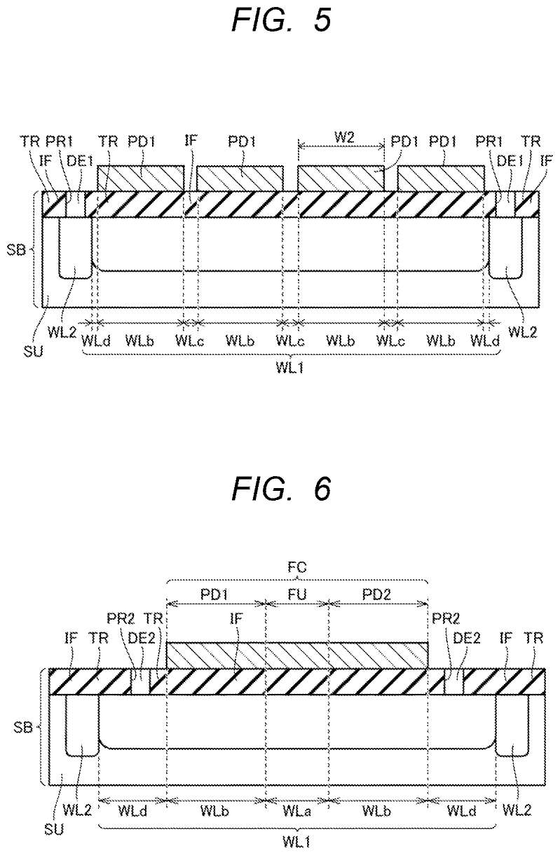

As shown in FIGS. 4 and 5, the convex portion PR1 is located over the second well region WL2. The diffusion region (first diffusion region) DE1 is disposed in the convex portion PR1. The diffusion region DE1 is, for example, a p-type impurity region. The diffusion region DE1 has a p-type impurity concentration higher than the p-type impurity concentration of the second well region WL2. The diffusion region DE1 and the second well region WL2 are electrically connected to each other, and the lower end of the diffusion region DE1 and the upper end of the second well region WL2 are connected to each other.

The convex portion PR1 serves to suppress a dishing that occurs on the upper surface of the dielectric film IF when the dielectric film IF is removed by CMP (Chemical Mechanical Polishing) so as to be left in the trench TR.

For this reason, the contact conductive layer in contact with the upper surface of the convex portion PR1 may not be formed on the diffusion region DE1 disposed in the convex portion PR1, but the contact conductive layer in contact with the upper surface of the convex portion PR1 may be formed. The potential of the second well region WL2 may be fixed through the diffusion region DE1 disposed in the convex portion PR1 by connecting the contact conductive layer to the convex portion PR1.

As shown in FIGS. 6 and 7, the convex portion PR2 is located over the first well region WL1. The diffusion region (second diffusion region) DE2 is disposed in the convex portion PR2. The diffusion region DE2 is, for example, an n-type impurity region. The diffusion region DE2 has an n-type impurity concentration equal to or higher than the n-type impurity concentration of the first well region WL1. The lower end of the diffusion region DE2 is connected to the upper end of the first well region WL1.

The convex portion PR2 serves to suppress a dishing that occurs on the upper surface of the dielectric film IF when the dielectric film IF is removed by CMP so as to be left in the trench TR. For this reason, the contact conductive layer in contact with the upper surface of the convex portion PR2 may not be formed on the diffusion region DE2 disposed in the convex portion PR2, but the contact conductive layer in contact with the upper surface of the convex portion PR2 may be formed. The potential of the first well region WL1 may be fixed through the diffusion region DE2 disposed in the convex portion PR2 by connecting the contact conductive layer to the convex portion PR2. The potential of the first well region WL1 may be a floating potential.

As shown in FIGS. 4 to 7, the dielectric film IF is disposed on the semiconductor substrate SB. As described above, the dielectric film IF fills the trench TR for STI. The upper surface of the dielectric film IF configures the same surface as the upper surface of each of the convex portions PR1, PR2.

The plurality of electric fuse cells FC are disposed on the dielectric film IF. Therefore, the plurality of electric fuse portions FU are also disposed on the dielectric film IF. The entire lower surface of each of the plurality of electric fuse cells FC is in contact with the upper surface of the dielectric film IF.

Each of the plurality of electric fuse cells FC includes, for example, a polysilicon layer in which n-type impurity is doped and a silicide layer disposed on the polysilicon layer. Therefore, each of the electric fuse portion FU, the first pad portion PD1, and the second pad portion PD2 of the electric fuse cell FC is formed of the polysilicon layer and the silicide layer. Each of the plurality of electric fuse cells FC is, for example, salicide.

As shown in FIG. 3, the second well region WL2 is disposed so as to surround the entire periphery of the first well region WL1. An arrangement region of the plurality of electric fuse cells FC is configured by arranging a plurality of arrangement regions FCR (regions surrounded by dashed-dotted lines in FIG. 3). One electric fuse cell FC is disposed in each of the plurality of arrangement regions FCR. The second well region WL2 is disposed so as to surround the arrangement region of the plurality of electric fuse cells FC in plan view.

The convex portion PR1 is disposed next to the electric fuse cell FC in the lateral direction (the direction in which the plurality of electric fuse portions FU are arranged) of the electric fuse portion FU in plan view. The two convex portions PR1 are disposed so as to sandwich the plurality of electric fuse cells FC in the lateral direction of the electric fuse portion FU in plan view. The plurality of electric fuse cells FC are disposed between the two convex portions PR1 in plan view.

The diffusion region DE1 disposed in the convex portion PR1 is located in a direction where the plurality of electric fuse portions FU are arranged with respect to the electric fuse cell FC in plan view. The two diffusion regions DE1 are disposed so as to sandwich the plurality of electric fuse cells FC in a lateral direction of the electric fuse portion FU in plan view. The plurality of electric fuse cells FC are disposed between the two diffusion regions DE1 in plan view. The diffusion region DE1 is not located in the intercell region between the electric fuse cells FC next to each other and is located outside the intercell region in plan view.

The convex portion PR2 is disposed next to the electric fuse cell FC in the longitudinal direction (the direction orthogonal to the direction in which the plurality of electric fuse portions FU are arranged) of the electric fuse portion FU. The two convex portions PR2 are disposed so as to sandwich one electric fuse cell FC in the longitudinal direction of the electric fuse portion FU in plan view. The electric fuse cell FC is disposed between the two convex portions PR2 in plan view.

The diffusion region DE2 disposed in the convex portion PR2 is located in a direction orthogonal to a direction in which the plurality of electric fuse portions FU are arranged with respect to the electric fuse cell FC in plan view. The two diffusion regions DE2 are disposed so as to sandwich the plurality of electric fuse cells FC in the longitudinal direction of the electric fuse portion FU in plan view. The electric fuse cell FC is disposed between two diffusion regions DE2 in plan view.

As shown in FIGS. 4 to 7, the first well region WL1 has regions WLa, WLb, WLc, WLd. The region WLa is a well region located under the electric fuse portion FU so as to overlap with the electric fuse portion FU in plan view. The region WLb is a well region located under the pad portions PD1, PD2 so as to overlap with the pad portions PD1, PD2 in plan view. The region WLc is a well region located under a region sandwiched between the electric fuse cells FC so as not to overlap with the electric fuse cell FC in plan view. The region WLd is a well region located in a region next to the second well region WL2 so as not to overlap with the electric fuse cell FC in plan view and sandwiched between the electric fuse cell FC and the second well region WL2 in plan view.

As shown in FIG. 4, the first well region WL1 is configured by integrally connecting the well region WLa located under each of the plurality of electric fuse portions FU. Specifically, the first well region WL1 is configured by integrally connecting the well region WLa located under each of the plurality of electric fuse portions FU to the other well regions WLb, WLc, WLd.

In the cross section of the electric fuse portion FU along the lateral direction, the well region WLc is sandwiched between the two well regions WLa next to each other. The both ends of the well region WLc is connected to the well region WLa. In the cross section of the electric fuse portion FU along the lateral direction, the well region WLd is sandwiched between the well region WLa and the second well region WL2. One end of the well region WLd is connected to the well region WLa, and the other end of the well region WLd forms a pn junction with the second well region WL2.

As shown in FIG. 5, in the cross section along the lateral direction of the electric fuse portion FU, the well region WLc is sandwiched between two well regions WLb next to each other. Both ends of the well region WLc is connected to the well region WLb. In the cross section along the lateral direction of the electric fuse portion FU, the well region WLd is sandwiched between the well region WLb and the second well region WL2. One end of the well region WLd is connected to the well region WLb, and the other end of the well region WLd forms a pn junction with the second well region WL2.

As shown in FIG. 6, in the cross section along the longitudinal direction of the electric fuse portion FU, the well region WLa is sandwiched between two well regions WLb next to each other. Both ends of the well region WLa is connected to the well region WLb. In the cross section along the longitudinal direction of the electric fuse portion FU, the well region WLd is sandwiched between the well region WLb and the second well region WL2. One end of the well region WLd is connected to the well region WLb, and the other end of the well region WLd forms a pn junction with the second well region WL2.

As shown in FIG. 3, the first well region WL1 is disposed in the entire region under the region sandwiched between the electric fuse cells FC next to each other in plan view. Specifically, as shown in FIG. 4, the well region WLc is sandwiched between two well regions WLa next to each other, and both ends of the well region WLc is connected to the well region WLa. Further, as shown in FIG. 5, the well region WLc is sandwiched between two well regions WLb next to each other, and both ends of the well region WLc are connected to the well region WLb.

As shown in FIG. 3, the trench TR and the dielectric film IF are disposed in the entire region under the region sandwiched between the electric fuse cells FC next to each other in plan view.

### Effect

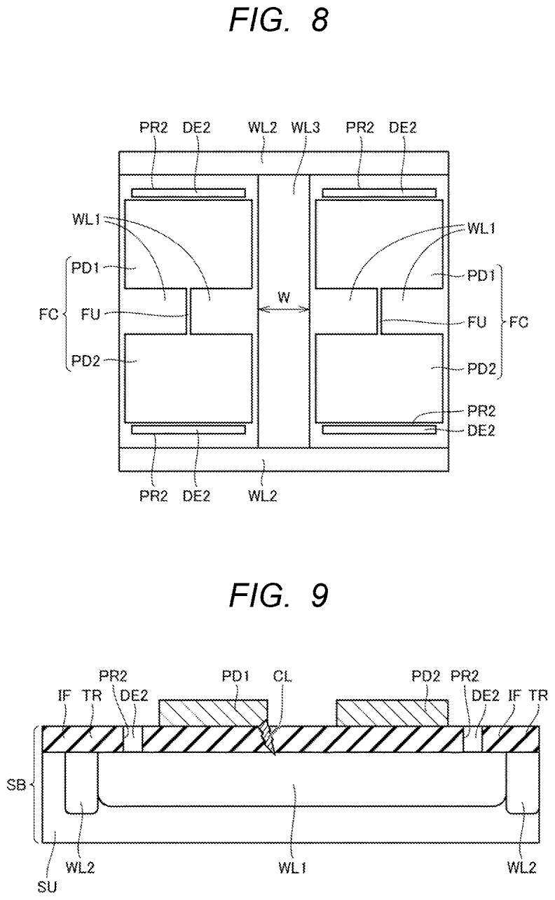

Hereinafter, the effects of the present embodiment will be described in comparison with the comparative example shown in FIG. 8.

In the comparative example shown in FIG. 8, the p-type impurity region WL3 is disposed under the region sandwiched between the two electric fuse cells FC in plan view. Both ends of the p-type impurity region WL3 form a pn junction with the n-type well region WL1 along the lateral direction of the electric fuse portion FU. That is, in the comparative example, the n-type well region WL1 is electrically isolated by the p-type impurity region WL3 for each electric fuse cell FC. In such a configuration of the comparative example, the distance between the electric fuse cells FC increases by an amount corresponding to the width W of the p-type impurity region WL3.

Since the electric fuse portion FU is fused and removed by energization, a large amount of current needs to flow through the electric fuse portion FU. Since a large amount of current flows through the electric fuse portion FU, the size of the cut transistor increases, and consequently, the size of the trimming circuit increases. Therefore, reducing the planar occupation area of the region in which the plurality of electric fuse cells FC are disposed is desired.

In the present embodiment, as shown in FIG. 4, the first well region WL1 is formed by integrally connecting the well region WLa located under each of the plurality of electric fuse portions FU to each other. Since the p-type impurity region WL3 as in the comparative example is not disposed between the well regions WLa next to each other, the distance between the electric fuse cells FC can be made smaller. Therefore, the planar occupation area of the region where the plurality of electric fuse portions FU are formed can be reduced.

In addition, in the present embodiment, as shown in FIGS. 3 to 5, the first well region WL1 is disposed in the entire region under the region sandwiched between the electric fuse cells FC next to each other. Accordingly, the distance between the electric fuse cells FC can be reduced.

Further, as shown in FIG. 9, when the electric fuse portion FU is fused, a conductive layer CL configuring the electric fuse portion FU rarely extend downward. In this case, when the power supply potential or the ground potential is applied to the first well region WL1, the power supply potential or the ground potential is also applied to the electric fuse portion FU through the conductive layer CL, and there is a possibility that it is not possible to correctly determine whether or not the electric fuse portion FU is fused. That is, even if the electric fuse portion FU is fused, there is a possibility that the electric fuse portion FU is determined not to be fused by continuing the current to the electric fuse portion FU when a part of the conductive layer CL extending downward reaches the first well region WL1 connected to the power supply potential or the grounding potential.

On the other hand, in the present embodiment, as shown in FIG. 4, when the potential of the first well region WL1 is the floating potential, even if the conductive layer CL extends as shown in FIG. 9, it is possible to correctly determine whether or not the electric fuse portion FU is fused, and therefore the reliability of the semiconductor device can be improved.

In the present embodiment, as shown in FIGS. 4 to 7, the semiconductor substrate SB has the trench TR, and the dielectric film IF fills the trench TR. As a result, the element isolation structure can be formed of STI, and compared to when the element isolation structure is formed of LOCOS (LOCal Oxidation of Silicon), the area of the element isolation structure in plan view can be reduced.

In the present embodiment, as shown in FIGS. 4 and 5, the trench TR and the dielectric film IF are disposed in the entire region under between the electric fuse cells FC next to each other. Therefore, the area of the element isolation structure in plan view can be reduced compared to when a LOCOS is used for the element isolation structure as described above.

In addition, in the present embodiment, as shown in FIG. 3, the diffusion region DE1 is located in the direction in which the plurality of electric fuse portions FU are arranged with respect to the electric fuse cell FC in plan view, is not located in the intercell region between the electric fuse cells FC next to each other, and is located outside the intercell region. As a result, the diffusion region DE1 is not located in the intercell region between the electric fuse cells FC next to each other, and thus the distance between the electric fuse cells FC is not increased.

In addition, since the convex portion PR1 in which the diffusion region DE1 is disposed is formed, dishing occurring on the upper surface of the dielectric film IF during CMP can be suppressed. As a result, variations in the dimensions of the electric fuse cell FC during the exposure process are suppressed when the electric fuse cell FC is formed on the dielectric film IF, and the yield of the electric fuse cell FC is improved.

In the present embodiment, as shown in FIG. 3, the diffusion region DE2 is located in a direction orthogonal to the direction in which the plurality of electric fuse portions FU are arranged with respect to the electric fuse cell FC in plan view. Accordingly, since the diffusion region DE2 is not located between the plurality of electric fuse portions FU, the distance between the electric fuse cells FC is not increased due to the diffusion region DE2.

In addition, since the convex portion PR2 in which the diffusion region DE2 is disposed is formed, dishing occurring on the upper surface of the dielectric film IF during CMP can be suppressed. As a result, variations in the dimensions of the electric fuse cell FC during the exposure process are suppressed when the electric fuse cell FC is formed on the dielectric film IF, and the yield of the electric fuse cell FC is improved.

### Second Embodiment

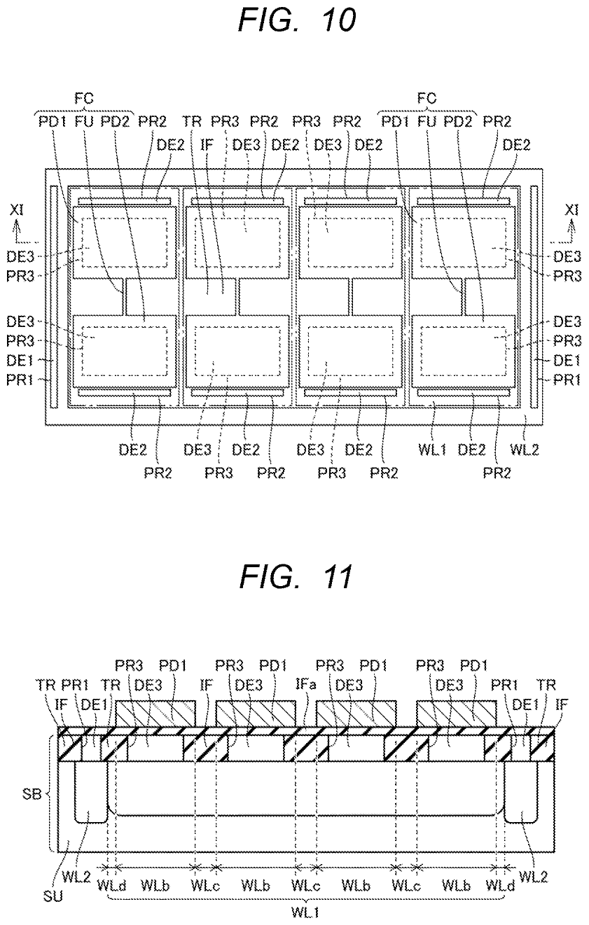

Next, a configuration of a semiconductor device according to the second embodiment will be described with reference to FIGS. 10 and 11.

As shown in FIGS. 10 and 11, the semiconductor device of the present embodiment differs from the first embodiment in that the semiconductor device of the present embodiment includes a convex portion (third convex portion) PR3 and a diffusion region (third diffusion region) DE3.

As shown in FIG. 11, the convex portion PR3 is disposed on the semiconductor substrate SB. The convex portion PR3 is a region where the trench TR is not formed on the surface of the semiconductor substrate SB. The convex portion PR3 protrudes upward from the bottom surface (bottom portion) of the trench TR. The convex portion PR3 is located next to the trench TR. The convex portion PR3 is located on the side surface of the trench TR.

The convex portion PR3 is located over the first well region WL1. The diffusion region DE3 is disposed in the convex portion PR3. The diffusion region DE3 is, for example, an n-type impurity region. The diffusion region DE3 has an n-type impurity concentration equal to or higher than the n-type impurity concentration of the first well region WL1. The lower end of the diffusion region DE3 is connected to the upper end of the first well region WL1.

The convex portion PR3 serves to suppress dishing that occurs on the upper surface of the dielectric film IF when the dielectric film IF is removed by CMP so as to be left in the trench TR. The convex portion PR3 has the same height as each of the convex portions PR1, PR2 from the bottom surface of the trench TR. The upper surface of the convex portion PR3 configures the same surface as the upper surface of the dielectric film IF.

As shown in FIG. 10, the convex portion PR3 is disposed under the pad portions PD1, PD2. As shown in FIG. 11, a dielectric film IFa is disposed between the upper surface of the convex portion PR3 and the electric fuse cell FC. The dielectric film IFa electrically isolates the convex portion PR3 and the electric fuse cell FC from each other.

Since the configuration of the present embodiment other than the above is substantially the same as the configuration of the first embodiment, the same elements are denoted by the same reference numerals, and descriptions thereof will not be repeated.

In the present embodiment, since the convex portion PR3 in which the diffusion region DE3 is disposed is formed, dishing occurring on the upper surface of the dielectric film IF during CMP can be further suppressed. As a result, variations in the dimensions of the electric fuse cell FC during the exposure process are suppressed when the electric fuse cell FC is formed on the dielectric film IF, and the yield of the electric fuse cell FC is further improved.

### Third Embodiment

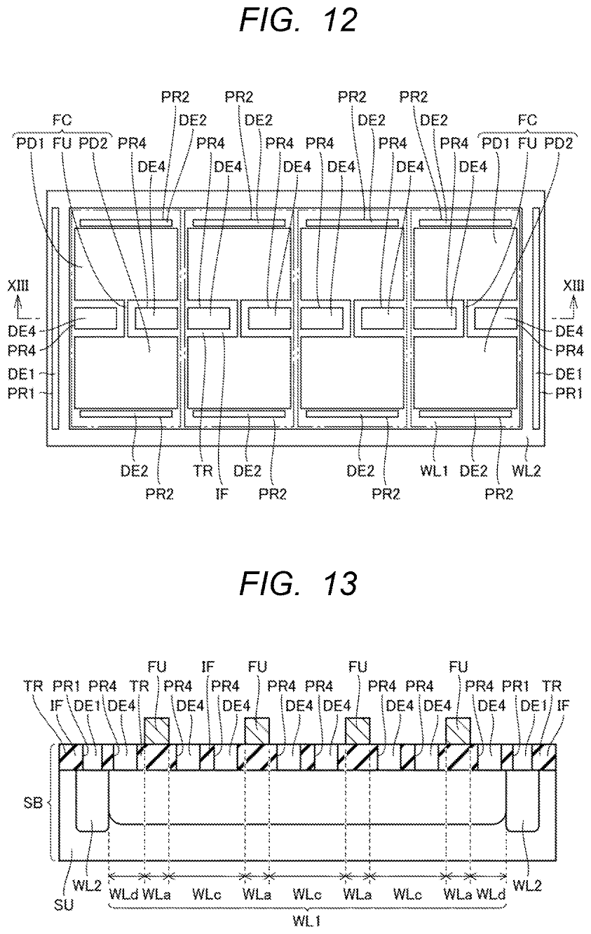

Next, a configuration of a semiconductor device according to the third embodiment will be described with reference to FIGS. 12 and 13.

As shown in FIGS. 12 and 13, the semiconductor device of the present embodiment differs from the first embodiment in that the semiconductor device of the present embodiment includes a convex portion (third convex portion) PR4 and a diffusion region (third diffusion region) DE4.

As shown in FIG. 13, the convex portion PR4 is disposed on the surface of the semiconductor substrate SB. The convex portion PR4 is a region where the trench TR is not formed on the surface of the semiconductor substrate SB. The convex portion PR4 protrudes upward from the bottom surface (bottom portion) of the trench TR. The convex portion PR4 is located next to the trench TR. The convex portion PR4 is located on the side surface of the trench TR.

The convex portion PR4 is located over the first well region WL1. The diffusion region DE4 is disposed in the convex portion PR4. The diffusion region DE4 is, for example, an n-type impurity region. The diffusion region DE4 has an n-type impurity concentration equal to or higher than the n-type impurity concentration of the first well region WL1. The lower end of the diffusion region DE4 is connected to the upper end of the first well region WL1.

The convex portion PR4 serves to suppress dishing that occurs on the upper surface of the dielectric film IF when the dielectric film IF is removed by CMP so as to be left in the trench TR. The convex portion PR4 has the same height as each of the convex portions PR1, PR2 from the bottom surface of the trench TR. The upper surface of the convex portion PR4 configures the same surface as the upper surface of the dielectric film IF.

As shown in FIG. 12, the convex portion PR4 is disposed between the electric fuse portions FU next to each other in plan view. Further, the convex portion PR4 is located in a region under between the electric fuse cells FC next to each other in plan view. The convex portion PR4 in which the diffusion region DE4 is disposed is located in a direction in which the plurality of electric fuse portions FU are arranged with respect to the electric fuse portion FU in plan view.

Since the configuration of the present embodiment other than the above is substantially the same as the configuration of the first embodiment, the same elements are denoted by the same reference numerals, and descriptions thereof will not be repeated.

In the present embodiment, since the convex portion PR4 in which the diffusion region DE4 is disposed is formed, dishing occurring on the upper surface of the dielectric film IF during CMP can be further suppressed. As a result, variations in the dimensions of the electric fuse cell FC during the exposure process are suppressed when the electric fuse cell FC is formed on the dielectric film IF, and the yield of the electric fuse cell FC is further improved.

The above-described semiconductor device in the embodiments and the modified example may be applied to a power supply IC (Integrated Circuit) products such as DC-DC (Direct Current-Direct Current) converters and PMIC (Power Management Integrated Circuit).

The dielectric film IFa in the second embodiment may be applied to the configurations of the first embodiment and the third embodiment.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a semiconductor substrate;
a dielectric film disposed on the semiconductor substrate;
a plurality of electric fuse portions disposed on the dielectric film; and
a first well region of a first conductivity type disposed in the semiconductor substrate and on a surface of the semiconductor substrate,
wherein the first well region is configured by integrally connecting a well region located under each of the plurality of electric fuse portions to each other.

2. The semiconductor device according to claim 1,
wherein each of a plurality of electric fuse cells is configured by one of the plurality of electric fuse portions and a pair of pad portions connected to both ends of the one of the plurality of electric fuse portions, and
wherein the first well region is disposed in a region under a region sandwiched between two electric fuse cells of the plurality of electric fuse cells next to each other.

3. The semiconductor device according to claim 1,
wherein a potential of the first well region is a floating potential.

4. The semiconductor device according to claim 2,
wherein the semiconductor substrate has a trench, and
wherein the dielectric film fills the trench.

5. The semiconductor device according to claim 4,
wherein the trench and the dielectric film are disposed in a region under between the two electric fuse cells of the plurality of electric fuse cells next to each other.

6. The semiconductor device according to claim 5, comprising:
a second well region of a second conductivity type different from the first conductivity type disposed in the semiconductor substrate so as to surround the first well region and forming a pn junction with the first well region; and
a first diffusion region of the second conductivity type disposed in a first convex portion of the semiconductor substrate protruded from a bottom portion of the trench, the first diffusion region being connected to the second well region,
wherein the first convex portion where the first diffusion region is disposed is located in a direction where the plurality of electric fuse portions are arranged with respect to the plurality of electric fuse cells in plan view, is not located in an intercell region between the two electric fuse cells of the plurality of electric fuse cells next to each other, and is located outside the intercell region.

7. The semiconductor device according to claim 5, comprising:
a second diffusion region of the first conductivity type disposed in a second convex portion of the semiconductor substrate protruded from the bottom portion of the trench,
wherein the second diffusion region is located in a direction orthogonal to the direction where the plurality of electric fuse portions are arranged with respect to the plurality of electric fuse cells in plan view.

8. The semiconductor device according to claim 1,
wherein each of the plurality of electric fuse portions includes a polysilicon layer and a silicide layer in contact with the polysilicon layer.

9. The semiconductor device according to claim 1, comprising:
a substrate region of the second conductivity type is disposed in the semiconductor substrate and forming a pn junction with the first well region.

10. The semiconductor device according to claim 5, comprising:
a third diffusion region of the first conductivity type disposed in a third convex portion of the semiconductor substrate protruded from the bottom portion of the trench,
wherein the third convex portion where the third diffusion region is disposed is located under one of the pair of the pad portions.

11. The semiconductor device according to claim 5, comprising:
a third diffusion region of the first conductivity type disposed in a third convex portion of the semiconductor substrate protruded from the bottom portion of the trench,
wherein the third convex portion where the third diffusion region is located in a direction where the plurality of electric fuse portions are arranged with respect to the plurality of electric fuse cells in plan view.

12. The semiconductor device according to claim 5, comprising:
a third diffusion region of the first conductivity type disposed in a third convex portion of the semiconductor substrate protruded from the bottom portion of the trench,
wherein the third convex portion where the third diffusion region is located in the region under between the two electric fuse cells of the plurality of electric fuse cells next to each other.
